(19) United States
(12) Patent Application Publication
(10) Pub. No.: US 2022/0036195 A1
(43) Pub. Date: Feb. 3, 2022

(54) METHOD FOR DECODING, COMPUTER PROGRAM PRODUCT, AND DEVICE

(71) Applicant: MITSUBISHI ELECTRIC CORPORATION, Tokyo (JP)

(72) Inventors: Vincent CORLAY, Rennes Cedex 7 (FR); Loic BRUNEL, Rennes Cedex 7 (FR); Philippe CIBLAT, Rennes Cedex 7 (FR); Joseph BOUTROS, Rennes Cedex 7 (FR)

(73) Assignee: MITSUBISHI ELECTRIC CORPORATION, Tokyo (JP)

(21) Appl. No.: 17/277,016

(22) PCT Filed: Aug. 26, 2019
(86) PCT No.: PCT/JP2019/034317

§ 371 Date: Mar. 17, 2021

(30) Foreign Application Priority Data
Oct. 29, 2018 (EP) 18306413.8

(51) Int. Cl. G06N 3/08; G06N 3/04; G06K 9/62; H03M 13/39

(52) U.S. Cl. CPC G06N 3/084; H03M 13/3944; G06K 9/6256; G06N 3/0481

(57) ABSTRACT

The invention relates to a method for decoding at least M₀ symbols X⁰₁, . . . , X⁰_{M0} received from a transmitter through a wireless communication medium, said received symbols representing symbols encoded by an encoder E of the transmitter, said method comprising: inputting in a decoder the M₀ symbols X⁰₁, . . . , X⁰_{M0}, said decoder comprising an artificial neural network system, wherein at least an activation function of the artificial neural network system is a multiple level activation function.

### TECHNICAL FIELD

The present invention relates to the decoding of data in a wireless communication system.

### BACKGROUND ART

It relates more precisely to artificial neural networks used for decoding of a received radio signal.

Traditionally, in a wireless communication system the transmitter and the receiver implement specific schemes with several components enabling to process the radio signal transmitting the data.

In FIG. 2 it is shown an example of a transmitter's scheme (referred to as transmitter scheme) and the corresponding receiver's scheme (referred to as receiver scheme) in a wireless communication system. The encoding/decoding of the radio signal in such system (transmitter and receiver) is crucial, a tradeoff between the rate of the transmission, the robustness of the transmission leading to decoding errors and the complexity of the receiver must be found.

However, recently artificial neural networks (ANN) have been used to replace components of the receiver, enabling to perform a more efficient decoding.

Nevertheless, efficient and accurate ANNs are still complex and therefore require an important amount of computing resources (CPU, GPU or dedicated hardware), which in the context of a wireless communication is a strong drawback.

The present invention aims at improving the situation.

### SUMMARY OF INVENTION

To that end, the invention relates to a method for decoding at least M₀ symbols X₁⁰, . . . , X_{M}_{₀}⁰ received from a transmitter through a wireless communication medium, said received symbols representing symbols encoded by an encoder E of the transmitter, said method comprising:

inputting in a decoder the M₀ symbols X₁⁰, . . . , X_{M}_{₀}⁰, said decoder comprising an artificial neural network system, wherein at least an activation function of the artificial neural network system is a multiple level activation function.

Data to be transmitted to a receiver is processed by a transmitter which applies to the data a scheme including an encoder E (for example: MIMO encoders, Lattice encoder) the scheme may also comprise other encoders and processing modules such as a MCS module and/or a Digital Analog Converter and/or a serial to parallel converter, etc. At the receiver side the radio signal received is decoded through a receiver scheme adapted to decode the radio signal processed by the scheme of the transmitter. That is, the receiver scheme may comprise modules corresponding to the modules of the transmitter scheme (for example an Analog Digital Converter, a MIMO decoders . . . ). The symbols outputted by the encoder E and processed by the modules of the transmitter scheme following the encoder E are transmitted through the radio communication channel (radio channel) to the receiver. The receiver applies the modules of the inverse scheme to that of the transmitter scheme, and obtains the M₀ symbols X₁⁰, . . . , X_{M}_{₀}⁰. These symbols represent at the receiver side the symbols outputted by the encoder E. These M₀ symbols are inputted in an artificial neural network decoder which decodes them and retrieves the symbols inputted in the encoder E.

At least one of the activation functions of the artificial neural network decoder is a multiple level activation function. A multiple level activation function is an activation function that enables to discriminate between more than two classes (at least three) and therefore consider more than two outputs (or levels of output) (at least 3), that is, at least three outputs (or levels of output).

The new telecommunication standards (for example, LTE, NR) implement encoders and decoders which process and produce an increasing number of symbols (For example, 256 QAM, any Lattice encoder, especially high spectral efficiency lattice-based encoder). That is, many values or symbols can be taken by the outputs and/or inputs of those decoders and encoders. Therefore, when replacing such decoder by an artificial neural network (ANN) decoder, the ANN decoder will face a high complexity on its outputs and/or inputs. This complexity does not affect only the inputs and outputs of the ANN system but propagates through the hidden layers of the ANN system. Therefore, the neurons (also referred as nodes) of the output layer as the neurons of the hidden layers may carry out the solving of multiclass classification problems, that is, to classify an element according to more than two classes. In this context and since a multiple level activation function (MLAF) enables multiclass classification at the output of a unique node/neuron, several nodes implementing regular activation functions (at the most 2 levels activation functions) may be replaced by one node implementing a MLAF. Therefore, an ANN decoder that uses MLAFs will need less neurons to decode the M₀ symbols. Therefore, by using less neurons, the complexity of the decoder decreases and less computing resources (CPU, GPU or dedicated hardware) are needed to decode the M₀ symbols.

In addition, when the number of layers and nodes is fixed, implementing MALFs in the nodes of the ANN system enables to enhance its accuracy.

By a multiple level activation function, it is understood an activation function that enables to consider strictly more than two levels of output. That is, an activation function that enables to discriminate input values in strictly more than two groups or classes. Therefore, a multiple level activation function of K levels with K strictly superior to 2, outputs K different groups of values, each group of values being easily discriminated. Advantageously, the inverse images of these groups under ƒ (where ƒ is the MLAF) are disjoint.

Advantageously, this discrimination property may be obtained with functions that exhibit at least three nearly constant regions. In other words, two inputs x₁ and x₂ are in the same group if |ƒ(x₂)−ƒ(x₁)| is negligible compared to |x₂−x₁| or at least lower than ε|x₂−x₁| with ε strictly smaller than 1, for example ε may be equal to ½, ⅕, 1/10 or 1/50.

Advantageously, this discrimination property may be obtained with functions for which two inputs x₁ and x₂ are in the same group if |ƒ(x₂)−ƒ(x₁)| is negligible compared to |ƒ(x₂)−ƒ(x₃)| or at least lower than ε|ƒ(x₂)−ƒ(x₃)| with x₂ and x₃ being in two different groups and with ε strictly smaller than 1, for example ε may be equal to ½, ⅕, 1/10 or 1/50.

By activation function it is understood a function that defines the output of a node (neuron) given its input. Activation functions share specific properties. For the sake of simplicity, when not specified as MLAF, activation function refers to regular activation function which is at the most 2 levels activation function. Regular activation functions are the activation functions known, by the person skilled in the art, to be used in the ANN system.

By symbols it is understood a real number belonging to a discrete set of numbers. The skilled person understands that complex symbols may be considered as two real symbols and therefore that the invention may be applied in the context of complex symbols.

By wireless communication medium it is understood a wireless communication system. That is, a system which enables transmitting data between a transmitter and a receiver using wireless technologies, generally radio waves, but can also be implemented with other wireless technologies, such as light, magnetic, or electric fields or the use of sound.

By ANN decoder it is understood a decoder, that is, a module of the receiver scheme that comprises at least one ANN system. The ANN decoder may comprise several ANN systems. For example, when the ANN decoder replaces MIMO decoders, an ANN system for each MIMO decoder may be implemented in the ANN decoder. For the sake of simplicity only an ANN decoder with a unique ANN system is described in the followings. Thus, the inputs and outputs of the ANN system coincide with the inputs and outputs of the ANN decoder.

By received symbols representing symbols encoded by an encoder E of the transmitter it is understood the symbols resulting from the processing of the symbols outputted by the encoder E by the transmitter according to the transmitter scheme and which have been received by the receiver. These received symbols may have been processed at the receiver side before being inputted in the ANN decoder. Indeed, the ANN decoder may not replace all the modules of the receiver scheme. For example, the ANN decoder may replace only a MIMO decoder (or several MIMO decoders) and therefore several modules are applied before inputting the symbols in the ANN decoder.

The decoder or more specifically the artificial neural network system can be defined as a function F which is defined by N sets of functions F₁ⁱ, . . . , F_{M}_{ᵢ}ⁱ, with i from 1 to N, Fₘⁱ(X₁ⁱ⁻¹, . . . , Xᵢ₋₁^{N-1})=ƒₘⁱ(Σₖ₌₁^{M}^{ᵢ₋₁} w_{k,m}ⁱ⁻¹×Xₖⁱ⁻¹+βₘⁱ), with F(X₁⁰, . . . , X_{M}_{₀}⁰)=[F₁^{N}(X₁ⁿ⁻¹, . . . , X_{M}_{_{N-1}}^{N-1})], . . . , F_{M}_{_{N}}^{N}(X₁^{N-1}, . . . , where, Xₘⁱ⁻¹ are respectively the outputs of the functions Fₘⁱ⁻¹, Xₘⁱ⁻¹=Fₘⁱ⁻¹(X₁ⁱ⁻², . . . , X_{M}_{ᵢ₋₁}²) of the (i−1)-th set, each ƒₘⁱ is either an artificial neural network activation function or an identity function, at least one of the ƒₘⁱ is not an identity function and w₁ⁱ⁻¹, . . . , w_{M}_{ᵢ₋₁}ⁱ⁻¹, βₘⁱ are real number parameters.

The set of functions F₁ⁱ, . . . , F_{M}_{ᵢ}ⁱ among the N sets represents the i-th layer of the ANN system/decoder. Therefore, the ANN system is a N-layer ANN system. Each function Fₘⁱ corresponds to a node of the i-th layer.

The parameters w_{1,m}ⁱ⁻¹, . . . , w_{M}_{ᵢ₋₁}ⁱ⁻¹, βₘⁱ for m from 1 to Mᵢ and i from 1 to N are real numbers that may be equal to zero, positive or negative.

According to an aspect of the invention, the artificial neural network system is trained on a training set of vectors \hat{Z}^{j}, each vector \hat{Z}^{j} being compared with the output of the artificial neural network system when applied to a vector \hat{X}^{j}, with \hat{X}^{j}=(\hat{X}₁^{0,j}, . . . , \hat{X}_{M}_{₀}^{0,j}), the vectors \hat{X}^{j} being obtained by applying respectively to the vectors \hat{Z}^{j} successively a first transformation representing the encoder E and a second transformation representing at least:
a part of a transmitting scheme of the transmitter, said part of the transmitting scheme following the encoder E, and
a radio communication channel.

By training the ANN system it is understood to apply a supervised learning method. For example, a backpropagation method can be implemented, using a training set of T vectors \hat{Z}^{j}, with j from 1 to T, and the corresponding set of vectors \hat{X}^{j}, each vector \hat{X}^{j} being obtained by applying transformations representing at least the transmitter scheme from the input of the encoder E to the emission of the transmission signal and a radio communication channel to the training set of vectors \hat{Z}^{j}. The second transformation may also represent the scheme applied at the receiver side from the reception of the radio signal to the input of the ANN system.

The output of the ANN system when applying the ANN system to the vector \hat{X}^{j}, is compared with the vector \hat{Z}^{j}, which is the ideal, or at least suitable, response of the ANN system regarding the vector \hat{X}^{j} (that is the input of the encoder E which results in the vector \hat{X}^{j}). The parameters of the ANN system are modified to reduce the overall gap between respectively the ideal responses and the actual responses of the ANN system regarding the vectors \hat{X}^{j}.

Advantageously, more than one vector \hat{X}^{j} may be obtained as previously described for each vector \hat{Z}^{j}. Indeed, there exist many possible transformations representing part of the transmitter scheme, the radio communication channel and part of the receiver scheme. For example, several transformations may represent a MIMO encoder, one for each pre-coding matrix. Several transformations may represent the radio communication channel, one transformation for each channel matrix and noise vector that can represent the radio communication channel. Therefore, each vector \hat{Z}^{j} can be associated with a group of vectors \hat{X}^{j,T}, with T from 1 to S. Two \hat{X}^{j,T} and \hat{X}^{j,T′} are obtained with different transformations T and T′ applied to the same vector \hat{Z}^{j}, each representing the same components of the transmitter and receiver schemes. However, each transformation may represent a different configuration of these components and/or a different radio communication channel. For the sake of simplicity, in the following only one vector \hat{X}^{j} is described for each vector \hat{Z}^{j}.

Mathematically, said parameters w₁ⁱ⁻¹, . . . , w_{M}_{ᵢ₋₁}ⁱ⁻¹, βₘⁱ, with i from 1 to N are computed to minimize a distance (also called a cost function) between respectively outputs F(\hat{X}₁^{0,j}, . . . , \hat{X}_{M}_{₀}^{0,j}) of the decoder and vectors \hat{Z}^{j} of a training set of vectors, with \hat{Z}^{j}=(\hat{Z}₁^{j}, . . . , \hat{Z}_{M}_{_{N}}^{j}). This optimization of the parameters is done to minimize the distance d(\hat{Z}^{j},F(\hat{X}^{j})) on all the training set. For example, by minimizing Σⱼ₌₁^{T} d(\hat{Z}^{j},F(\hat{X}^{j})) or Σⱼ₌₁^{T} aⱼ·d(\hat{Z}^{j},F(\hat{X}^{j})), with aⱼ a strictly positive real number. The distance d may be for example the Euclidean distance, square Euclidean distance or the cross-entropy.

In the context of ANN systems replacing decoders in receiver schemes, since the complexity of these ANN systems decreases when implementing at least one MLAF, the training of such ANN systems requires less computing resources (CPU, GPU or dedicated hardware).

By a transformation representing a scheme and/or a radio communication channel it is understood a mathematical representation of the scheme and/or of the radio communication channel. For example, the radio communication channel may be represented by a channel matrix and a noise vector.

By part of the transmitting/receiving scheme it is understood one or several components (also referred as modules) of the transmitting/receiving scheme that are successively applied to produce/process the radio signal.

The radio communication channel can be generalized with any wireless communication channel that can for example be mathematically represented or encountered in a given environment. Therefore, in the case of a wireless communication system based on other wireless technologies other representations of the communication channel will be made.

According to an aspect of the invention, the multiple level activation function may be defined as:

$${f}_{K , {B}_{1} , … , {B}_{K - 1} , A , {τ}_{1} , … , {τ}_{K - 1}} ( x ) = {{\sum }^{K - 1}}_{l = 1} {B}_{l} {f}_{l} ( x - {τ}_{l} ) + A$$

with each ƒₗ being a regular activation function (to which we refer as activation function when not specified that it is a MLAF, that is at the most a 2 levels activation function),
with τₗ being real numbers, and if l≠l′=>τₗ≠τ_{l′},
with A and the Bₗ being real numbers,
and K a positive integer greater than or equal to 3.

This definition enables to easily produce MLAFs adapted to each or at least several nodes of the ANN system, when implementing several MLAFs in an ANN system. Therefore, depending on the structure and the computing carried out by the ANN system (resulting from the problem solved by the ANN system) the MLAFs can be adapted. In addition, the parameters K, B₁, . . . , B_{K-1}, A, τ₁, . . . , τ_{K-1} can be set previously to the training of the ANN system or they can be considered as the parameters of the ANN system which are modified to reduce the overall gap between respectively the ideal responses and the actual responses of the ANN system regarding the vectors \hat{X}^{j}. Each of the MLAF can be parametrized differently. The activation functions ƒₗ may be the same or different. However, the activation functions ƒₗ used are activation functions that enable to discriminate inputs values in two groups or classes (that is at the most 2 levels activation functions), for example Logistic function, Heaviside step function, Hyperbolic tangent function (Tan H), arctangent function, Softsign function, Rectified linear unit function (ReLu), Leaky rectified linear unit function (Leaky ReLU), Parametric rectified linear unit function (PReLU), Randomized leaky rectified linear unit function (RReLU), Exponential linear unit function (ELU), Scaled exponential linear unit function (SELU), SoftPlus function, Sigmoid-weighted linear unit function (SiLU), Sigmoid function, Maxout function.

K is the number of levels discriminated. The MLAF ƒ_{K,B}_{₁}_{, . . . , B}_{_{K-1}}_{,A,τ}_{₁}_{, . . . , τ}_{_{K-1}} (x) is therefore a K-levels MLAF.

All the following multiple level activation functions may be defined as a function ƒ_{K,B}_{₁}_{, . . . , B}_{_{K-1}}_{,A,τ}_{₁}_{, . . . , τ}_{_{K-1}} (x) with potentially different parameters.

According to an aspect of the invention, the inputs of the encoder E are connected to the outputs of a Modulation encoder.

Therefore, the ANN decoder outputs sequences of symbols as defined by the modulation scheme used. The ANN decoder aims at retrieving the symbols to which are applied the encoder E, the following scheme of the transmitter, and which are received by the receiver and inputted in the ANN decoder. Modules of the transmitter may be applied to the received signal to obtain the M₀ symbols inputted in the ANN decoder.

The modulation decoder may be a modulation and coding scheme decoder. However, the modulation scheme applied by the decoder can be of any sort, for example the symbols of the modulation scheme can be complex (QPSK, QAM) or real (PAM). Optionally, a P/S module may be implemented between the ANN decoder and the Modulation decoder (also referred to as a demodulator).

According to an aspect of the invention, at least one of the functions ƒₘ^{N} with m from 1 to M_{N}, is a multiple level activation function.

In this case at least one of the activation functions on the output layer of the ANN system, that is, one of the function ƒₘ^{N}, with m from 1 to M_{N} is a multiple level activation function. The outputs of the ANN system correspond to modulation symbols, which are then inputted in the Modulation decoder. Since in the modulation schemes several symbols are used, more than 2 real symbols (except for example in BPSK), using multiple level activation function on the output layer of the ANN system enables to use less nodes on the output layer to output all the possible symbols of the modulation scheme. Indeed, by using a MLAF the output of which may take K distinctive values (K greater than 2) enables to distinguish K different symbols at the output of the MLAF. For example, if the modulation scheme comprises K symbols, then using a K-level MLAF on the output layer of the ANN system enables to represent all the different symbols of the modulation scheme at the output of a unique activation function. Therefore, it enables to reduce the number of nodes needed to output values enabling to represent all the symbols of the modulation scheme.

More specifically, when symbols of the modulation scheme used by the Modulation encoder are each defined by P coordinates (q₁; . . . ; q_{P}), it is advantageous to use on the output layer of the ANN system at least P′ functions (ƒₘ_{₁}^{N}, . . . , ƒₘ_{_{p′}}^{N}) among the functions ƒₘ^{N}, with m from 1 to M_{N}, which respectively output values of P′ coordinates among the P coordinates (q₁; . . . ; q_{P}) and wherein each ƒₘ_{ₖ}^{N} is a Kₖ-level activation function, where Kₖ is equal to the number of values that can take the k-th coordinate among the P′ coordinates of the symbols of the modulation type.

By modulation type it is understood a modulation scheme.

Therefore, the outputs of a number of MLAFs equal to the dimension of the modulation scheme, that is, for example the dimension of the constellation diagram, may enable to represent all the symbols of the modulation scheme.

According to an aspect of the invention, all the functions ƒₘ^{N} with m from 1 to M_{N}, are multiple level activation functions.

As previously mentioned, the MLAFs of the output layer of the ANN system may be of the type ƒ_{K,B}_{₁}_{, . . . , B}_{_{K-1}}_{,A,τ}_{₁}_{, . . . , τ}_{_{K-1}} (x)=Σₗ₌₁^{K-1} Bₗ ƒₗ(x−τₗ)+A. The parameters of these MLAFs may be different.

According to an aspect of the invention, the encoder E comprises a Lattice encoder, and the inputs of the Lattice encoder are the inputs of the encoder E.

Therefore, the ANN decoder replaces at least a Lattice decoder.

By Lattice encoder it is understood an encoder which outputs an n-tuple of real numbers Σᵢ₌₁ⁿ zᵢ eᵢ∈ [symbol] ⁿ when at its input it is inputted an n-tuple of integers (z₁, . . . , zₙ)∈ [symbol] ⁿ, with (e₁, . . . , eₙ) a basis of [symbol] ⁿ, that is eᵢ∈ [symbol] ⁿ and the (e₁, . . . , eₙ) are linearly independent. That is, for each n-tuple of integers (z₁, . . . , zₙ)∈ [symbol] ⁿ the encoder outputs a unique point or element of a lattice in [symbol] ⁿ.

Therefore, the ANN decoder outputs n-tuple of integers (z₁, . . . , zₙ)∈ [symbol] ⁿ.

The input of the Lattice encoder may be a Pulse-amplitude modulation (PAM) encoder which outputs integers. For example, a 4-level PAM will input in the Lattice encoder integers among 0, 1, 2 and 3.

According to an aspect of the invention, at least one of the functions ƒₘⁱ with m from 1 to Mᵢ and i from 1 to N−1 is a multiple level activation function.

As previously mentioned, the MLAFs of the hidden layers of the ANN system may be of the type ƒ_{K,B}_{₁}_{, . . . , B}_{_{K-1}}_{,A,τ}_{₁}_{, . . . , τ}_{_{K-1}} (x)=Σₗ₌₁^{K-1} Bₗ ƒₗ(x−τₗ)+A. The parameters of these MLAFs may be different.

This enables to reduce the numbers of nodes needed in the ANN decoder and thus reduces the complexity of the decoder which therefore requires less computing resources (CPU, GPU or dedicated hardware) to decode the M₀ symbols.

According to an aspect of the invention, the encoder E comprises a MIMO encoder.

Therefore, the ANN decoder may replace at least one or several MIMO decoders for example by implementing one ANN system for each MIMO decoder or one ANN system for all the MIMO decoders. In addition, using the ANN decoder to replace at least a MIMO decoder and another module enables to optimize the use of the ANN decoder. Indeed, it is possible to train an ANN system to replace MIMO decoders and another module, for example a lattice decoder, without modifying the number of layers which would have been used in a ANN system replacing only a lattice decoder or at least adding to that ANN system a number of layers smaller than the number of layers necessary for an ANN system to replace only a MIMO decoder. Even though the number of layers is reduced, the number of nodes per layer may increase or the accuracy of the ANN system may be reduced, therefore in such context it is possible to replace groups of nodes by MLAFs enabling to reduce or at least to maintain the level of complexity of the ANN system when the ANN system replaces more than one module.

A second aspect of the invention concerns a computer program product comprising code instructions to perform the method as described previously when said instructions are run by a processor.

A third aspect of the invention concerns a device for receiving M₀ symbols X₁⁰, . . . , X_{M}_{₀}⁰ from a transmitter through a wireless communication medium, said received symbols representing symbols encoded by an encoder E of the transmitter, the device comprises:
a reception module; and
a decoder, said decoder comprising an artificial neural network system, wherein at least an activation function of the artificial neural network system is a multiple level activation function.

The present invention is illustrated by way of example, and not by way of limitation, in the figures of the accompanying drawings, in which like reference numerals refer to similar elements.

### BRIEF DESCRIPTION OF DRAWINGS

FIG. 1 illustrates a transmitter and receiver according to the invention.

FIG. 2 schematizes a block diagram of a classical MIMO transmitter and a classical MIMO receiver.

FIG. 3 schematizes a block diagram of a MIMO transmitter and a MIMO receiver respectively implementing a Lattice encoder and a Lattice decoder.

FIG. 4 illustrates a two-dimensional Lattice.

FIG. 5 schematizes an ANN system.

FIG. 6 schematizes a block diagram of a classical MIMO transmitter and a receiver implementing a ANN decoder according to the invention.

FIG. 7 schematizes a block diagram of a MIMO transmitter implementing a Lattice encoder and a MIMO receiver implementing an ANN-Lattice decoder according to the invention.

FIG. 8 illustrates a MLAF according to the invention.

FIG. 9 illustrates a flowchart representing the decoding of a radio signal according to the invention.

### DESCRIPTION OF EMBODIMENTS

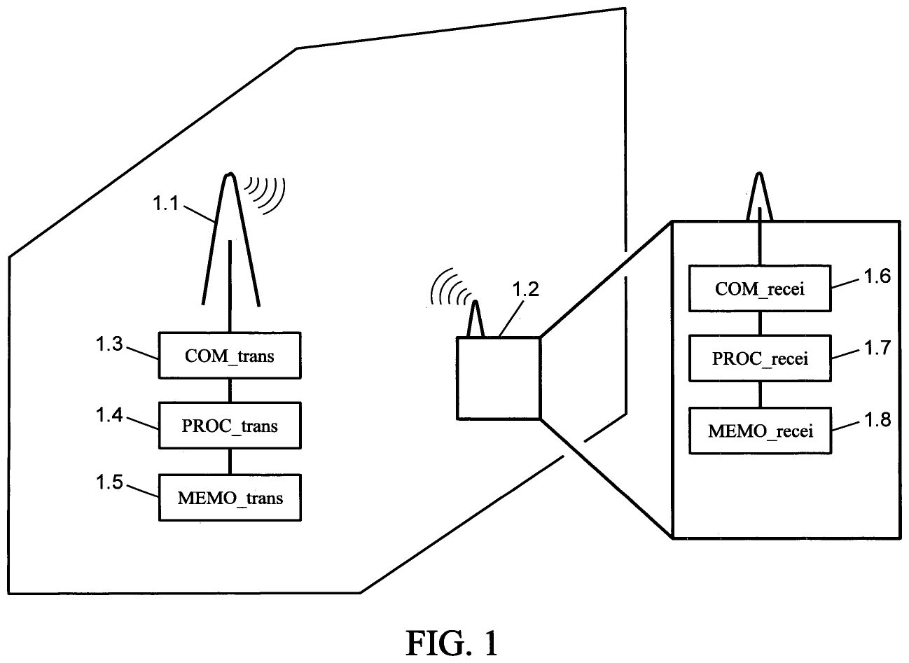

Referring to FIG. 1, it is showed a transmitter 1.1 transmitting a radio signal to a receiver 1.2. The receiver 1.2 is in the cell coverage of the transmitter 1.1. This transmission may be an OFDM based transmission. In this example the receiver 1.2 is a mobile terminal and the transmitter 1.1 is a fixed station which in the context of LTE is a base station. The transmitter 1.1 can as well be the mobile terminal and the receiver 1.2 a fixed station. Both, the transmitter 1.1 and the receiver 1.2 may be mobile terminals.

The transmitter 1.1 comprises one communication module (COM_trans) 1.3, one processing module (PROC_trans) 1.4 and a memory unit (MEMO_trans) 1.5. The MEMO_trans 1.5 comprises a non-volatile unit which retrieves the computer program and a volatile unit which retrieves the parameters of the transmitter scheme (Modulation scheme applied, etc.). The PROC_trans 1.4 is configured to process the data to transmit according to the transmitter scheme including the encoder E. The COM_trans 1.3 is configured to transmit to the receiver 1.2 the radio signal. The processing of the data intended to be transmitted may also be realized by the COM_trans 1.3 rather than by the PROC_trans 1.4, in that case the PROC_trans 1.4 configures the COM_trans 1.3 to perform this processing. Indeed, the processing may be performed by electronic circuits dedicated to the processing of the data according to the transmitter scheme, or the processing may be performed by processors which process the data according to the transmitter scheme. The invention is not limited to such implementations and encompasses any combination of electronic and computing processing to process the data according to the transmitter scheme.

The receiver 1.2 comprises one communication module (COM_recei) 1.6, one processing module (PROC_recei) 1.7 and a memory unit (MEMO_recei) 1.8. The MEMO_recei 1.8 comprises a non-volatile unit which retrieves the computer program and a volatile unit which retrieves the parameters of the receiver scheme (Demodulation scheme applied, parameters of the ANN decoder obtained during the training, etc.). The PROC_recei 1.7 is configured to process the radio signal received from the transmitter according to the receiver scheme including the ANN decoder which has been previously trained. The COM_recei 1.6 is configured to receive from the transmitter the radio signal. The processing of the radio signal to retrieve the data may also be realized by the COM_recei 1.6 rather than by the PROC_recei 1.5, in that case the PROC_recei 1.5 configures the COM_recei 1.6 to perform this processing. Indeed, the processing may be performed by electronic circuits dedicated to the processing of the radio signal according to the transmitter scheme, or the processing may be performed by processors which process the radio signal according to the transmitter scheme. The invention is not limited to such implementations and encompasses any combination of electronic and computing processing to process the radio signal according to the transmitter scheme. When the ANN decoder is implemented by an electronic circuit, this electronic circuit may be a programmable logic device, which enables to adapt the ANN system according to training parameters defined during the training of the ANN system.

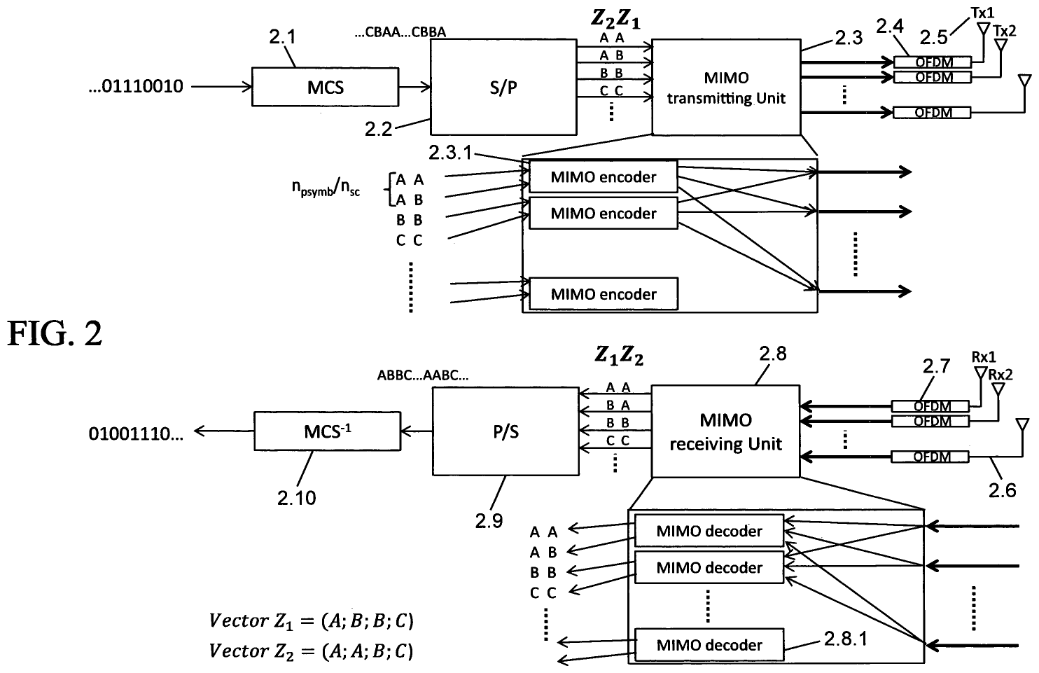

Referring to FIG. 2, it is showed a block diagram of a classical MIMO transmitter and a classical MIMO receiver.

The radio signal is obtained by processing data in the transmitter scheme. That is, by applying to a binary sequence, which represents the data to be transmitted, a modulation and coding scheme (MCS) encoder 2.1. The MCS encoder 2.1 outputs a sequence of symbols which are taken from a specific digital modulation scheme, for example, a QAM for which each symbol is considered as two real symbols in the following. These symbols are represented in FIG. 2 by letters ( . . . CBAA . . . CBBA). A serial to parallel module (S/P) 2.2 is then applied to the sequence of symbols to output n_{psym} parallel symbols, 4 parallel symbols in the example of FIG. 2. These n_{psym} parallel symbols (Z₁ or Z₂ in FIG. 2) are then inputted in the MIMO transmitting unit 2.3 which inputs in each of the n_{OFDM/Tx} OFDM encoders 2.4 n_{sc} parallel symbols (where n_{sc} is the number of subcarriers used to carry symbols, also called useful subcarriers, that is non null subcarriers). The symbols outputted by the MIMO transmitting unit 2.3 are obtained according to pre-coding matrices that configures the MIMO transmitting unit 2.3. More specifically, the n_{psym} parallel symbols are respectively inputted by groups of n_{psymb}/n_{sc} parallel symbols in each of the n_{sc} MIMO encoders 2.3.1. Each MIMO encoder 2.3.1, which is parameterized according to a pre-coding matrix, outputs n_{OFDM/Tx} symbols which are respectively inputted on the same subcarrier in each of the n_{OFDM/Tx} OFDM encoders 2.4. Therefore, each OFDM encoder 2.4 receives one symbol from each MIMO encoder 2.3.1 (i.e. n_{sc} symbols from n_{sc} different MIMO encoders, one for each subcarrier), that is each OFDM encoder 2.4 receives n_{sc} parallel symbols from the MIMO transmitting unit 2.3.

Each OFDM encoder 2.4 processes the n_{sc} parallel symbols received at its input by applying an IFFT (Inverse fast Fourier transform) module and DACs (Digital Analog Converter). The output of each OFDM encoder 2.4 is emitted on one antenna Tx 2.5.

The radio signal is received by the receiver 1.2 on each of its n_{OFDM/Rx} antennas Rx 2.6. To each signal received is applied an OFDM decoder 2.7. Each of the OFDM decoders 2.7 of the receiver 1.2 outputs n_{sc} parallel symbols which are inputted in the MIMO receiving unit 2.8. The MIMO receiving unit 2.8 decodes the n_{OFDM/Rx} groups of n_{sc} symbols respectively outputted by the OFDM decoders 2.7 according to pre-coding matrix by which it has been configured. The MIMO receiving unit 2.8 outputs n_{psym} symbols to which are applied successively a parallel to serial module 2.9 and a MCS decoder 2.10, that is, a demodulator and a decoding module, or simply a demodulator. More specifically, each OFDM decoder 2.7 inputs n_{sc} parallel symbols respectively in the n_{sc} MIMO decoders 2.8.1, that is one symbol in each MIMO decoder 2.8.1. Each inputted symbol in the MIMO receiving unit 2.8 is inputted in one of the n_{sc} MIMO decoders 2.8.1. Each MIMO decoder 2.8.1 receives from each OFDM decoder 2.7 a symbol from the same subcarrier and outputs n_{psymb}/n_{sc} symbols according to a pre-coding matrix to which it has been configured. That is, the n_{sc} MIMO decoders 2.8.1. output n_{psymb} parallel symbols.

If the radio channel did not affect too much the radio signal and the noise of the different systems (transmitter 1.1 and receiver 1.2) is limited, the binary sequences emitted by the transmitter 1.1 are retrieved at the receiver 1.2 side.

Each OFDM decoder 2.7 applies on the signal received by their corresponding antenna Rx 2.6 ADCs (Analog Digital Converter) and a FFT (Fast Fourier transform) module which outputs n_{sc} symbols.

In the case of the invention which implements such scheme, antenna ports implementing another scheme than an Orthogonal frequency-division multiplexing (OFDM) scheme may be implemented.

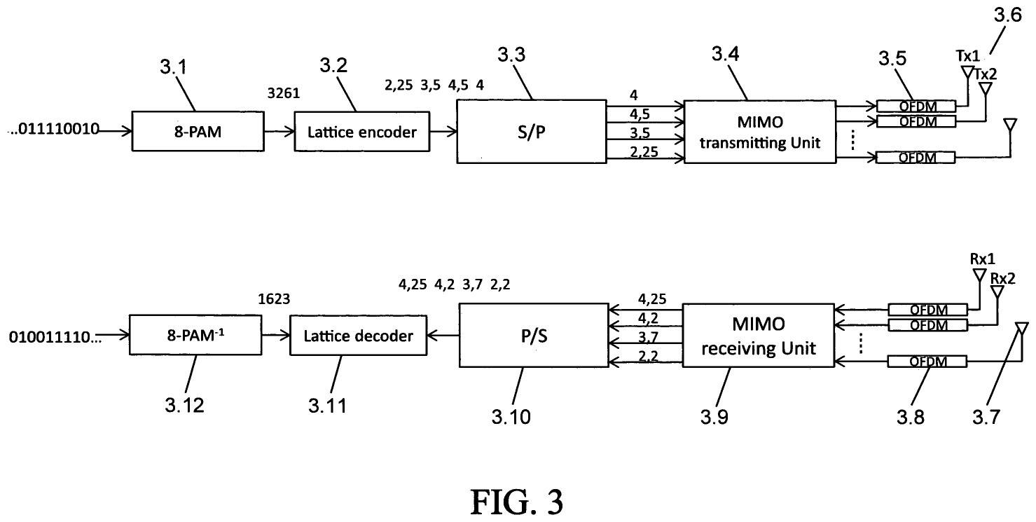

Referring to FIG. 3, it is showed a block diagram of a classical MIMO transmitter and a MIMO receiver respectively implementing a lattice encoder and a lattice decoder.

The radio signal is provided by processing data, and more specifically binary sequences, in the transmitter scheme. The transmitter scheme is the same as the one described in FIG. 2 except that the MCS encoder 2.1 is replaced by a modulator 3.1 and a Lattice encoder 3.2. The modulator 3.1 outputs values which can be associated with integers (for example different levels of amplitude of a signal in a Pulse-amplitude modulation (PAM) modulator).

Each output of the modulator 3.1 may be associated to a number of integers, this number being equal for example to the dimension of the constellation diagram of the modulation scheme used by the modulator 3.1. For example, with a PAM modulator 3.1 the dimension of the constellation diagram is equal to one, therefore, each symbol is represented by one integer also named level.

Based on n_{Lat}-tuple of integers (z₁, . . . , zₙ)∈ [symbol] ⁿ outputted by the modulator 3.1, the Lattice encoder 3.2 outputs n_{Lat}-tuple of real numbers Σᵢ₌₁ⁿ zᵢ eᵢ∈ [symbol] ⁿ, with (e₁, . . . , eₙ) a basis of a Lattice (therefore a basis of [symbol] ⁿ), that is eᵢ∈ [symbol] ⁿ and the (e₁, . . . , eₙ) are linearly independent. This transformation (z₁, . . . , zₙ)→Σᵢ₌₁ⁿ zᵢ eᵢ is an isomorphism represented by the matrix G, the rows of which are basis vectors.

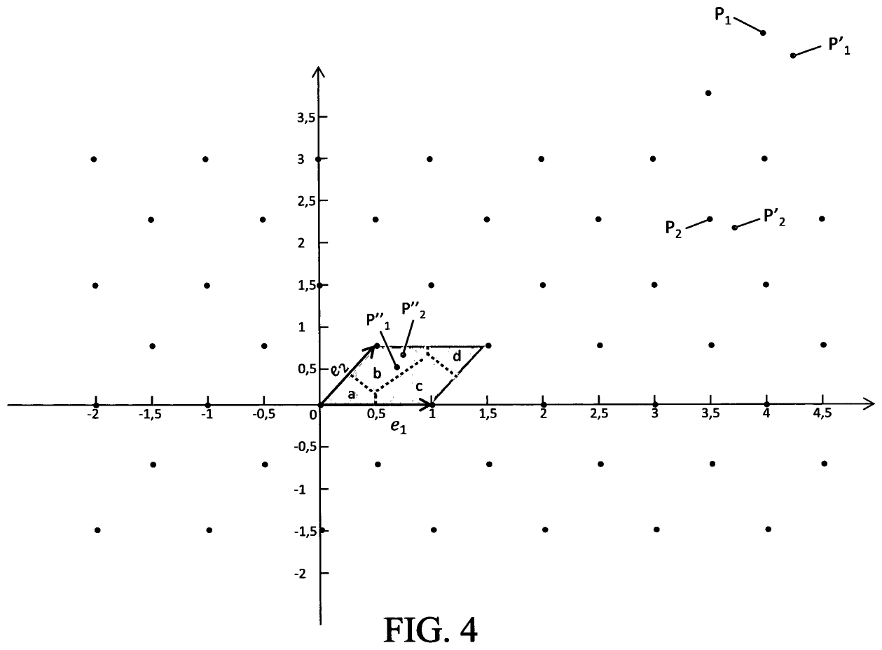

In the example of FIG. 4 is schematized a two-dimensional Lattice. The points of this lattice (represented in dots on FIG. 4) are defined as (z₁ e₁+z₂e₂) with (z₁,z₂)∈ [symbol] ². Since Vector (e₁)=(1; 0) and Vector (e₂)=(0.5; 0.75) a point (z₁ e₁+z₂e₂) of the Lattice is equal to

$$( {Z}_{1} + \frac{1}{2} {Z}_{2} , \frac{3}{4} {Z}_{2} ) .$$

Therefore, for a sequence of integers (1; 6; 2; 3) outputted by the modulator 3.1, the Lattice encoder 3.2 outputs (4; 4.5; 3.5; 2.25), with (4; 4.5) and (3.5; 2.25) two points of the Lattice P₁ and P₂.

The n_{Lat}-tuple of real numbers Σᵢ₌₁ⁿ zᵢ eᵢ∈ [symbol] ⁿ is inputted in a serial to parallel module (S/P) 3.3 which outputs n_{psym} parallel symbols, 4 parallel symbols in the example of FIG. 3. From the inputting of the sequence of n_{Lat} real numbers in the S/P module 3.3 to the emission of the radio signal, the transmitter scheme is identical to the one described in FIG. 2. That is, at the output of the S/P module 3.3 is applied a MIMO transmitting unit 3.4 (as described in FIG. 2) and each OFDM encoder 3.5 process the n_{sc} parallel symbols received at his input. The output of each OFDM encoder 35 is emitted on each antenna Tx 3.6.

The radio signal is received by the receiver 1.2 on each of its n_{OFDM/Rx} antennas Rx 3.7. From the antennas Rx 3.7 to the output of the P/S module 3.10, the receiver scheme is identical to the one described in FIG. 2. Indeed, to each signal received is applied an OFDM decoder 3.8. Each of the OFDM decoder 3.8 of the receiver 1.2 outputs n_{sc} parallel symbols which are inputted in the MIMO receiving unit 3.9. The MIMO receiving unit 3.9 decodes the n_{OFDM/Rx} group of n_{sc} symbols respectively outputted by the OFDM decoders 3.8. The MIMO receiving unit 3.9 outputs n_{psym} symbols (as described in FIG. 2) to which are applied a parallel to serial module 3.10.

The P/S module 3.10 outputs a sequence of real numbers. These real numbers are inputted in the Lattice decoder 3.11 to be processed by tuples of n_{Dim} real numbers (n_{Dim}=n_{Lat}), where n_{Dim} is the dimension of the Lattice to which has been configured the Lattice decoder 3.11. Each n_{Dim}-tuple of real numbers inputted in the Lattice decoder 3.11, represents a point of [symbol] ⁿ. In the example of FIG. 4, the points P′₁ (4.25; 4.20) and P′₂ (3.70; 2.20) of [symbol] ⁿ represent the two n_{Dim}-tuple of real numbers. The noise and the canal have altered the symbols outputted by the Lattice encoder 3.2. Therefore, the n_{Dim}-tuple of real numbers does not correspond to a point of the Lattice. The Lattice decoder 3.2 determines to which point of the Lattice the point of [symbol] ⁿ inputted in the decoder 3.2 is the closest. For this purpose the Lattice decoder may process each of these points by:
computing └P′₁G⁻¹┘ and P″₁=P′₁−└P′₁G⁻¹┘G, P″₁ being the point in the grey parallelogram representing the Fundamental domain of the Lattice, with └X┘ being defined as └Vector(X₁; . . . ; Xₙ)┘=Vector(└X₁┘; . . . ; └Xₙ┘) where └Xᵢ┘ is the floor function;
determining the closest Lattice point C₁ to the point P″₁ in the Fundamental domain; and
computing C′₁=C₁+└P′₁ G⁻¹┘G.

To determine the closest Lattice point C, to the point P″₁ in the Fundamental domain, the Lattice decoder 3.11 may determine the position of the point P″₁ regarding several hyperplanes which divide the Fundamental domain in different zones (a, b, c, d, obtained with 5 hyperplanes in the case of FIG. 4), the points of each zone being closer to one of the Lattice points of the Fundamental domain. The hyperplanes are the line segment bisector of each segment of the Fundamental domain. In FIG. 4, P″₁ and P″₂ are in the zone b, therefore, both are closer to the lattice point at the up left of the Fundamental domain.

Therefore, if the radio channel did not affect too much the radio signal and the noise of the different systems (transmitter 1.1 and receiver 1.2) is limited, the Lattice decoder 3.11 retrieves the correct Lattice point and thus retrieves the correct sequence of integers (z₁, . . . , zₙ) ((1; 6; 2; 3) in the case of FIG. 4). This sequence of integers is transformed into a binary sequence via the demodulator 3.12, which enables to retrieve, at the receiver 1.2 side, the binary sequences emitted by the transmitter 1.1.

The Lattice encoder 3.2 and Lattice decoder 3.11 are defined by their Lattice. That is, for each Lattice encoder/decoder there exists a unique lattice representation.

In the case of the invention which implements such scheme, antennas ports implementing another scheme than an Orthogonal frequency-division multiplexing (OFDM) scheme may be implemented.

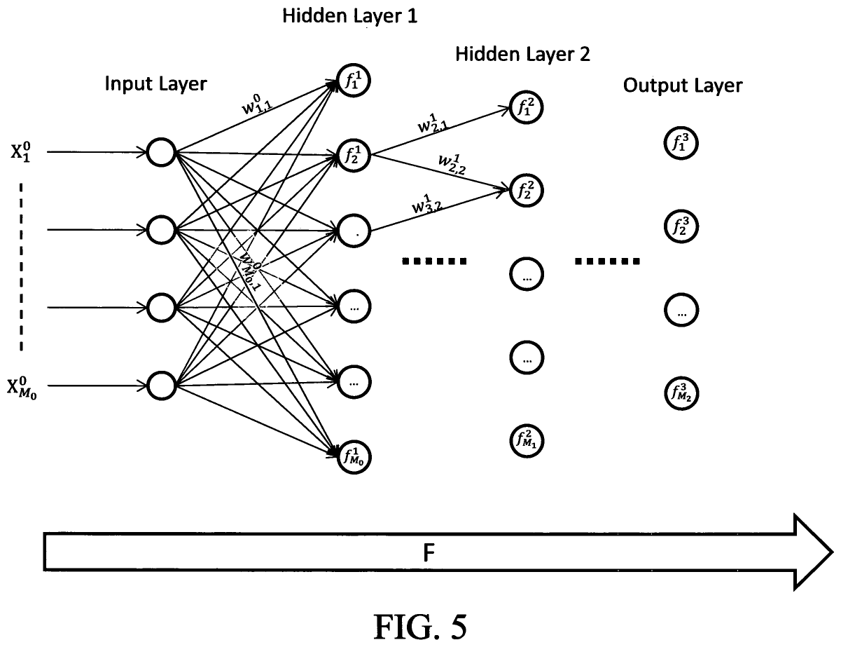

FIG. 5 schematizes an ANN system. An ANN system is defined by layers, an input layer, one or more hidden layers and one output layer. Except for the input layer, each layer is composed of nodes to which are inputted weighted values of the previous layer. Input values are inputted in the nodes of the input layer.

Therefore, as represented in FIG. 5, X₁⁰, . . . , X_{M}_{₀}⁰ values are inserted in the input layer. The m-th node of the i-th layer of the ANN system, that is, the node (i; m) can be represented by Fₘⁱ(X₁ⁱ⁻¹, . . . , X_{M}_{ᵢ₋₁}ⁱ⁻¹)=ƒₘⁱ(Σₖ₌₁^{M}^{ᵢ₋₁} w_{k,m}ⁱ⁻¹×Xₖⁱ⁻¹+βₘⁱ),where ƒₘⁱ is an activation function, and Σₖ₌₁^{M}^{ᵢ₋₁} w_{k,m}ⁱ⁻¹×Xₖⁱ⁻¹ is the weighted sum of the values Xₖⁱ⁻¹ outputted by each node of the previous layer, w_{k,m}ⁱ⁻¹ being the weights. In addition, a value βₘⁱ is added to this sum, this value is called a bias or an offset.

The ANN system can therefore be represented by a function F such as F(X₁⁰, . . . , X_{M}_{₀}⁰)=[F₁^{N}(X₁^{N-1}, . . . , X_{M}_{_{N-1}}^{N-1}), . . . , F_{M}_{_{N}}^{N}(X₁^{N-1}, . . . , X_{M}_{_{N-1}}^{N-1})]. A ANN decoder may comprise several ANN systems.

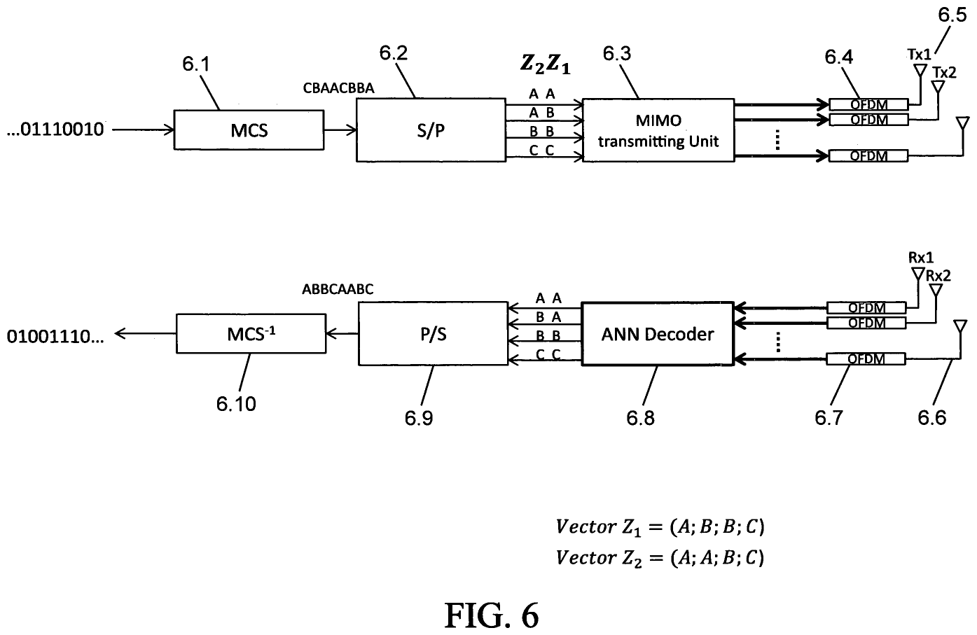

Referring to FIG. 6 it is showed a block diagram of a classical MIMO transmitter and a receiver implementing a ANN decoder.

The scheme of the transmitter 1.1 is identical to the one described in FIG. 2. That is, the transmitter scheme implements successively a MCS encoder 6.1, a S/P module 6.2, a MIMO transmitting unit 6.3, OFDM encoders 6.4 and transmitting antennas Tx 6.5.

The scheme of the receiver 1.2 is identical to the one described in FIG. 2 except that the MIMO receiving unit 2.8 is replaced by a ANN decoder 6.8. That is, the receiver scheme implements successively receiving antennas Rx 6.6, OFDM decoders 6.7, a ANN decoder 6.8, a P/S module 6.9 and a MCS decoder 6.10, all the elements being identical except for the MIMO receiving unit 2.8.

Indeed, the MIMO receiving unit 2.8 is replaced by an ANN decoder 6.8, that is, a decoder comprising at least an ANN system as described in the FIG. 5. The decoder may be an ANN system or simply a part of the decoder may be ANN system, that is, for example adding pre-processing by a decision feedback equalizer decoder. The decoder may also comprise several ANN systems, for example one ANN system for each MIMO decoder in the MIMO receiving unit 2.8. For the sake of simplicity only an ANN system completely replacing the decoder is described.

As for the MIMO transmitting unit 2.8 of FIG. 2, the ANN decoder 6.8 receives on its inputs the n_{sc} groups of n_{OFDM/Rx} symbols outputted by the OFDM decoders 6.7. For example, the ANN decoder 6.8 implements an input layer with a node for each of the n_{OFDM/Rx}×n_{sc} symbols, that is, an input layer containing n_{OFDM/Rx}×n_{sc} nodes. The ANN decoder 6.8 processes those inputs, and each of the nodes of the output layer outputs a value. The outputted values of the n_{psym} nodes of the output layer represent the n_{psym} parallel symbols.

The symbols of the modulation scheme inputted in the MCS decoder 6.10 may be represented in a P-dimensional space. The P-dimensional space may be the constellation diagram but other representations of the symbols of the modulation type may be chosen, for example all the symbols may be associated with values in a one-dimensional space. However, each symbol of the modulation scheme is defined by P coordinates (q₁; . . . ; q_{P}). The coordinates are real numbers. Therefore, when complex symbols are considered, or more generally complex values, each of them may be decomposed on two coordinates since the ANN system implements activation functions which are [symbol] to [symbol] functions.

The ANN decoder 6.8 may be configured so that at least P′ functions (ƒₘ_{₁}^{N}, . . . , ƒₘ_{_{P′}}^{N}) among the functions ƒₘ^{N}, that is, P′ activation functions of the output layer may be MLAF. The P′ functions (ƒₘ_{₁}^{N}, . . . , ƒₘ_{_{P′}}^{N}) respectively output values of P′ coordinates among the P coordinates (q₁; . . . ; q_{P}). When P′=P the output taken by (ƒₘ_{₁}^{N}, . . . , ƒₘ_{_{P′}}^{N}) represents a point in the P-dimensional space in which are represented the symbols of the modulation type. However, each ƒₘ_{ₖ}^{N} is a Kₖ-levels activation function, where Kₖ is equal to the number of values that can take the k-th coordinate among the P′ coordinates of the symbols of the modulation type. When P′=P, the number of possible points outputted by (ƒₘ_{₁}^{N}, . . . , ƒₘ_{_{P′}}^{N}) is at least equal to the number of symbols of the modulation scheme.

Generally, P′ is smaller than P, in that case the output layer of the ANN system outputs the P coordinates (q₁; . . . ; q_{P}) in several times, that is, for example, outputting the first P′ coordinates of the symbol and then the second P′ coordinates of the symbol and so on.

The MLAF that are chosen may be defined as:

ƒₘ_{ₖ}^{N}(x)=Σₗ₌₁^{K}^{ₖ}⁻¹B_{l,k}ƒ_{l,k}(x−τ_{l,k})+Aₖ

Each ƒ_{l,k} are activation functions (regular activation function), these activation functions may be the same activation function or different activation functions. In the following, for the sake of simplicity the ƒ_{l,k} will all be the same for l from 1 to Kₖ−1 and k from 1 to P, such activation function will be noted ƒ. ƒ may be for example a hyperbolic tangent (Tan H).

The τ_{l,k} are distinct real numbers, that is, if l≠l′=>τ_{l,k}≠τ_{l′,k}. This distinction between the τ_{l,k} ensures that the activation function has several levels.

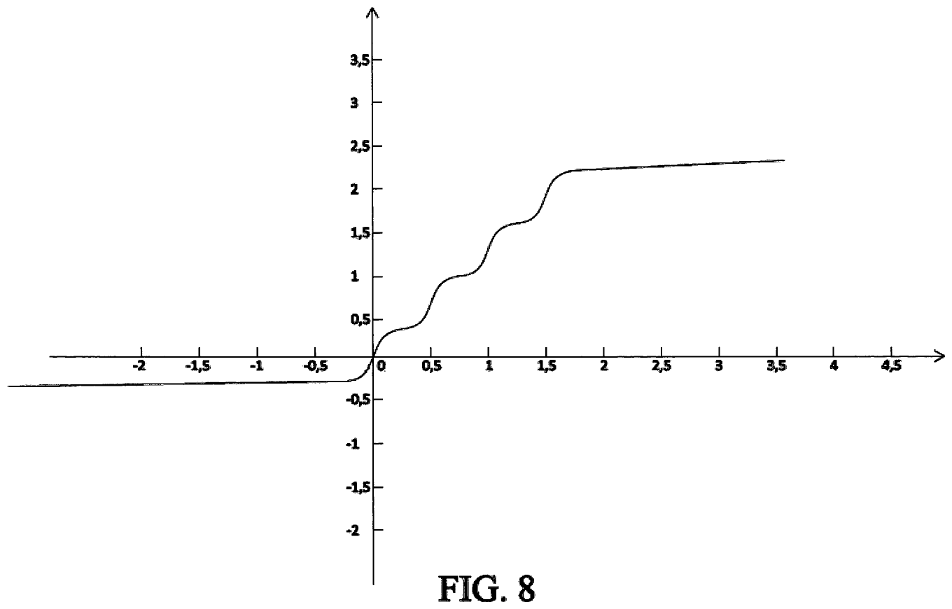

The Aₖ and the B_{l,k} are real numbers. In FIG. 8 is shown an example of MLAF function with 5 levels, with the ƒ_{l,k} being hyperbolic tangent functions.

At least for one k from 1 to P′, Kₖ is a positive integer greater than or equal to 3. Indeed, most of the representation in a P-dimensional space of a modulation scheme is done in a compact manner, that is, all the Kₖ are similar or equal to each other. For example, for k and k′ from 1 to P′, Kₖ is either equal to K_{k′}, K_{k′}+1 or K_{k′}−1. In addition, in the modulation scheme used in the new communication standard the number of symbols is important, which involves that the Kₖ, for k from 1 to P′, are all greater than 3. For example, with a QAM modulation scheme of 8 symbols, at least one activation function may be a MLAF (with strictly more than 2 levels), with a QAM modulation type of 16 symbols, two activation functions may be MLAFs with each 4 levels.

When considering that the P′ coordinates of each of the symbols of the modulation type used by the MCS decoder 6.10 is represented by one of the possible output of the P′ functions (ƒₘ_{₁}^{N}, . . . , ƒₘ_{_{P′}}^{N}) then all the P′ coordinates of the different symbols of the modulation scheme can be represented by the output values of only P′ Kₖ-levels activation functions, whereas it would have been necessary to use at least Σₖ₌₁^{P′} Kₖ−1 classical activation functions. Therefore, implementing classical activation functions would necessitate adding a significant amount of nodes in the output layer.

To enable the ANN decoder 6.8 to output the values representing the correct symbols according to the n_{OFDM/Rx}×n_{sc} symbols inputted in the ANN decoder 6.8, the ANN decoder 6.8 is trained. Therefore, previously to the processing at the receiver side, the ANN decoder 6.8 is trained. The training aims at modifying the parameters of the ANN system, that is w_{1,m}ⁱ⁻¹, . . . , w_{M}_{ᵢ₋₁}ⁱ⁻¹, m, βₘⁱ with m from 1 to Mᵢ and i from 1 to N, so that when the receiver 1.2 receives a radio signal resulting from a specific symbol inputted in the MIMO transmitting unit 6.3 of the transmitter 1.1, the output taken by (ƒₘ_{₁}^{N}, . . . , ƒₘ_{_{P′}}^{N}), which represents the P′ coordinates of a point in the P-dimensional space, is as close as possible to the specific symbol.

The training is performed based on a training set of vectors \hat{Z}^{j}, with j from 1 to T. In the case of FIG. 6, each vector \hat{Z}^{j} is an input of the MIMO transmitting unit 6.3. Each vector \hat{Z}^{j} is associated with at least a vector \hat{X}^{j} obtained by applying to the vectors \hat{Z}^{j} successive transformations representing part of the transmitter scheme (transformations representing the MIMO transmitting unit 6.3, the OFDM encoders 6.4 and transmitting antennas Tx 6.5), the radio communication channel (represented for example by a channel matrix and a noise vector) and part of the receiver scheme (transformations representing the receiving antennas Rx 6.6 and the OFDM decoders 6.7).

Each vector \hat{Z}^{j} may be associated with more than one vector \hat{X}^{j} as previously defined. Indeed, there exist many possible successive transformations representing part of the transmitter scheme, the radio communication channel and part of the receiver scheme. For example, several transformations may represent each MIMO encoder of the MIMO transmitting unit 6.3, one transformation for each pre-coding matrix to which may be configured the MIMO encoders. Several transformations may represent the radio communication channel, one transformation for each channel matrix and noise vector that can represent the radio communication channel. More generally, several transformations may represent each component of the transmitter scheme, the receiver scheme and the radio communication channel. Therefore, each vector \hat{Z}^{j} is associated with a group of vectors \hat{X}^{j,T} with T from 1 to S. Two \hat{X}^{j,T} and \hat{X}^{j,T′} are obtained with different transformations T and T′ applied to the same vector \hat{Z}^{j}, each representing the same components of the transmitter and receiver. However, each transformation may represent a different configuration of these components and/or a different radio communication channel.

The training of the ANN decoder 6.8 comprises comparing respectively the vectors \hat{Z}^{j} with the outputs of the ANN decoder 6.8 when the vectors \hat{X}^{j,T} are inputted to it. If the ANN decoder 6.8 is represented by the function F as described in FIG. 5, then \hat{Z}^{j} is compared to F(\hat{X}^{j,T}) with \hat{X}^{j,T} equal to (\hat{X}₁^{0,j,T}, . . . , \hat{X}_{M}_{₀}^{0,j,T}). The comparison may be made by a distance d. That is, the distances d(\hat{Z}^{j}; F(\hat{X}^{j,T})) are computed for each pair (T; j).

The parameters w_{1,m}ⁱ⁻¹, . . . , w_{M}_{ᵢ₋₁}ⁱ⁻¹, m, βₘⁱ, with m from 1 to Mᵢ and i from 1 to N are computed to minimize the distance on the whole training set of vectors \hat{Z}^{j}.

For example, the parameters w_{1,m}ⁱ⁻¹, . . . , w_{M}_{ᵢ₋₁}ⁱ⁻¹, m, βₘⁱ may be computed to minimize for example Σ_{j,T} d(\hat{Z}^{j}; F(\hat{X}^{j,T})) or Σ_{j,T} αⱼ·[d(\hat{Z}^{j}; F(\hat{X}^{j,T}))], where the aⱼ are weighting factors. The parameters w_{1,m}ⁱ⁻¹, . . . , w_{M}_{ᵢ₋₁}ⁱ⁻¹, m, βₘⁱ influence the values taken by F(\hat{X}^{j,T}).

The parameters w_{1,m}ⁱ⁻¹, . . . , w_{M}_{ᵢ₋₁}ⁱ⁻¹, m, βₘⁱ may be computed with a stochastic gradient descent method, where the values of the gradient are obtained with a backpropagation method. Backpropagation is an algorithm used to efficiently compute the gradient of the cost function with respect to the weights used in the network.

For the sake of simplicity, in the above description the S/P module 6.2 has not been taken into account in the training process, indeed, rigorously the vectors \hat{Z}^{j} are not outputs of the MCS encoder 6.1 but outputs of the S/P module 6.2. However, the S/P module 6.2 has not been taken into account since it only changes the training set of row vectors \hat{Z}^{j} to a set of column vectors (\hat{Z}^{j})^{tr}, that is the transpose of the vectors \hat{Z}^{j}.

The parameters Kₖ, B_{1,k}, . . . , B_{K}_{ₖ}_{-1,k}, A, τ_{1,k}, . . . , τ_{K}_{ₖ}_{-1,k} of each ƒₘ_{ₖ}^{N}(x) can be set previously to the training of the ANN decoder 6.8 or they can be considered as the parameters of the ANN decoder 6.8 which are modified to reduce the overall gap between respectively the ideal responses and the actual responses of the ANN decoder 6.8. In that case the parameters are w_{1,m}ⁱ⁻¹, . . . , w_{M}_{ᵢ₋₁}ⁱ⁻¹, m, βₘⁱ, with m from 1 to Mᵢ and i from 1 to N and Kₖ, B_{1,k}, . . . , B_{K}_{ₖ}_{-1,k}, A, τ_{1,k}, . . . , τ_{K}_{ₖ}_{-1,k} for k from 1 to P.

In the embodiment of FIG. 6 the ANN decoder replaces only the MIMO receiving unit 2.8. Here, the skilled person understands that the ANN decoder may replace additional components of the receiver scheme settled upstream from the MCS decoder 6.10. For example, the ANN decoder may replace the MIMO receiving unit 2.8 and the OFDM decoders 2.7.

Here, the skilled person understands that other schemes than the ones implemented in the transmitter 1.1 and the receiver 1.2 could be implemented. The embodiment described in FIG. 6 may be transposed with other schemes to the condition that there is a modulator and a demodulator. In that case, the ANN decoder may replace the component which outputs are inputted into the modulator and any component placed before.

Here, the skilled person understands that the ANN system implemented could be different from the feed forward neural network described in FIG. 5, for example, the ANN implemented could be a recurrent neural network.

In the embodiment of FIG. 6, it is only described to set MLAFs on the output layer. However, the complexity of the outputs of ANN decoder propagates through the hidden layers of the ANN system. Therefore, it may be relevant to set MLAFs in the hidden layers.

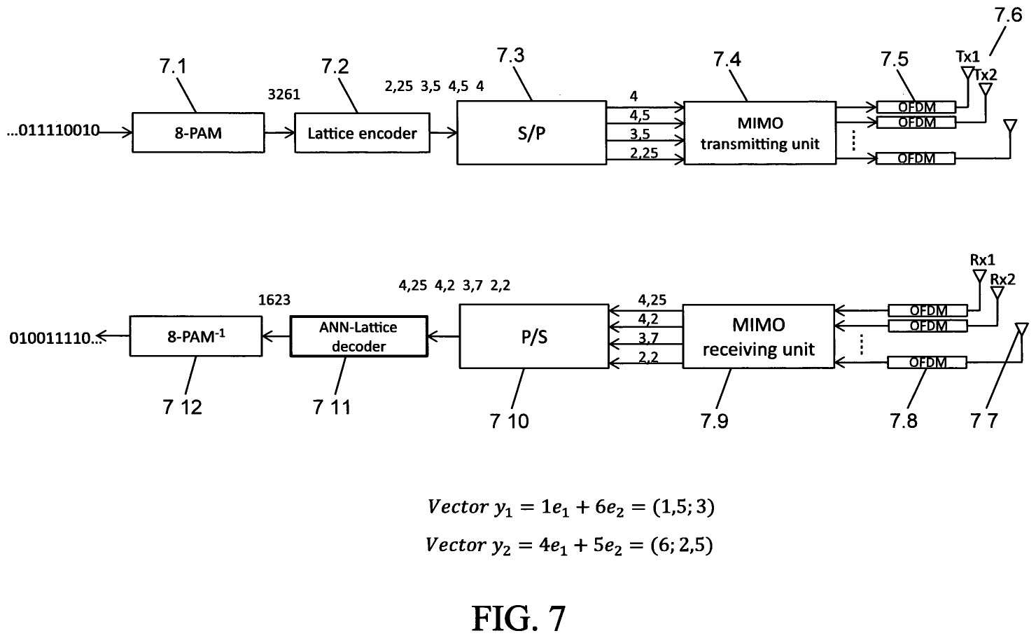

Referring to FIG. 7 it is showed a block diagram of a classical MIMO transmitter implementing a Lattice encoder and a MIMO receiver implementing an ANN-Lattice decoder according to the invention.

The scheme of the transmitter 1.1 is identical to the one described in FIG. 3. That is, the transmitter scheme implements successively a modulator 7.1, a Lattice encoder 7.2, a S/P module 7.3, a MIMO transmitting unit 7.4, OFDM encoders 7.5 and transmitting antennas Tx 7.6.

The scheme of the receiver 1.2 is identical to the one described in FIG. 3 except that the Lattice decoder 3.11 is replaced by an ANN-Lattice decoder 7.11. That is, the receiver scheme implements successively receiving antennas Rx 7.7, OFDM decoders 7.8, a MIMO receiving unit 7.9, a P/S module 7.10, an ANN-Lattice decoder 7.11 and a demodulator 7.12, all the elements being identical except for the Lattice decoder 3.11.

Indeed, the Lattice decoder 3.11 is replaced by an ANN-Lattice decoder 7.11, that is, a decoder comprising an ANN system as described in the FIG. 5. The decoder may be an ANN system or simply a part of the decoder may be ANN system. For the sake of simplicity only an ANN system completely replacing the Lattice decoder is described.

As for the Lattice decoder 3.11 of FIG. 3, the ANN-Lattice decoder 7.11 receives on its inputs tuples of n_{Dim} real numbers outputted by the P/S module 7.10, with n_{Dim} being the dimension of the Lattice to which has been configured the Lattice encoder 7.2. The tuple of n_{Dim} real numbers represents a point of [symbol] ⁿ.

The ANN-Lattice decoder 7.11 processes those inputs, and each of the nodes of the output layer outputs a value. These outputted values represent a sequence of n_{Dim} integers. For example, n_{Dim} nodes of the output layer each output an integer. In that case, these n_{Dim} nodes may implement n_{Dim} MLAFs

$$( {f}_{{m}_{1}}^{N} , … , {f}_{{m}_{{n}_{Dim}}}^{N} )$$

among the functions ƒₘ^{N}. Each of the ƒₘ_{ₖ}^{N} outputs values corresponding to the k-th element of the sequence of n_{Dim} integers. In addition each ƒₘ_{ₖ}^{N} may be a Kₖ-levels activation function, where Kₖ is equal to the number of values that can be taken by the k-th element of the sequences of n_{Dim} integers outputted by the modulator 3.1.

The number of nodes on the output layer may be smaller than n_{Dim}. In that case, and as described in FIG. 6, the output layer of the ANN system outputs the n_{Dim} integers in several times. For the sake of simplicity n_{Dim} is considered as smaller than the number of nodes on the output layer.

For the sake of simplicity the n_{Dim} MLAFs may all be K levels activation functions, with K equal to the maximum integer that can output the modulator 7.1. For example, with a 8-level PAM modulator 7.1, the n_{Dim} MLAFs may all be 8 levels activation functions. Therefore, the number of values that can be outputted by each ƒₘ_{ₖ}^{N} is at least equal to the number of symbols of the modulation scheme used by the modulator 7.12.

When considering that each of the integer of the sequence of integers (the integers being symbols of the modulation scheme used by the modulator 7.12) is represented by the output of one of ƒₘ_{ₖ}^{N} then all the different sequences of n_{Dim} integers outputted by the modulator 7.1 can be represented by the output values of

$$( {f}_{{m}_{1}}^{N} , … , {f}_{{m}_{{n}_{Dim}}}^{N} ) .$$

To enable the ANN-Lattice decoder 7.11 to output the values representing the correct sequences of n_{Dim} integers according to the tuples of n_{Dim} real numbers inputted, the ANN-Lattice decoder 7.11 is trained. That is, previously to the processing at the receiver side, the ANN-Lattice decoder 7.11 is trained. The training aims at modifying the parameters of the ANN system, that is w_{1,m}ⁱ⁻¹, . . . , w_{M}_{ᵢ₋₁}ⁱ⁻¹, m, βₘⁱ with m from 1 to Mᵢ and i from 1 to N, so that when the receiver 1.2 receives a radio signal resulting from a specific sequence of n_{Dim} integers inputted in the Lattice encoder 7.2 of the transmitter 1.1, the sequence of values outputted by

$$( {f}_{{m}_{1}}^{N} , … , {f}_{{m}_{{n}_{Dim}}}^{N} ) ,$$

is as close as possible to that specific sequence.

The training is performed based on a training set of vectors \hat{Z}^{j}∈ [symbol] ⁿ^{_{Dim}}, with j from 1 to T. In the case of FIG. 7, each vector \hat{Z}^{j} is an input of the Lattice encoder 7.2. Each vector \hat{Z}^{j} is associated with at least a vector \hat{X}^{j}∈ [symbol] ⁿ^{_{Dim}} obtained by applying to the vectors \hat{Z}^{j} successive transformations representing part of the transmitter scheme (transformations representing the Lattice encoder 7.2, the S/P module 7.3, the MIMO transmitting unit 7.4, the OFDM encoders 7.5 and the transmitting antennas Tx 7.6), the radio communication channel (represented for example by a channel matrix and a noise vector) and part of the receiver scheme (transformations representing the receiving antennas Rx 7.7, the OFDM encoders 7.8, the MIMO receiving unit 7.9 and the P/S module 7.10).

Each vector \hat{Z}^{j} may be associated with more than one vector \hat{X}^{j} as previously defined. Indeed, there exist many possible successive transformations representing part of the transmitter scheme, the radio communication channel and part of the receiver scheme. For example, several transformations may represent each MIMO encoder of the MIMO transmitting unit 7.4, one transformation for each pre-coding matrix to which may be configured the MIMO encoders. Several transformations may represent the radio communication channel, one transformation for each channel matrix and noise vector that can represent the radio communication channel. More generally, several transformations may represent each component of the transmitter scheme, the receiver scheme and the radio communication channel. Therefore, each vector \hat{Z}^{j} is associated with a group of vectors \hat{X}^{j,T}, with T from 1 to S. Two \hat{X}^{j,T} and \hat{X}^{j,T′} are obtained with different transformations T and T′ applied to the same vector \hat{Z}^{j}, each representing the same components of the transmitter and receiver. However, each transformation may represent a different configuration of these components and/or a different radio communication channel.

The training of the ANN-Lattice decoder 7.11 comprises comparing respectively the vectors \hat{Z}^{j} with the outputs of the ANN-Lattice decoder 7.11 when the vectors \hat{X}^{j,T} are inputted to it. If the ANN-Lattice decoder 7.11 is represented by the function F as described in FIG. 5, then \hat{Z}^{j} is compared to F(\hat{X}^{j,T}) with \hat{X}^{j,T} equal to (\hat{X}₁^{0,j,T}, . . . , \hat{X}_{M}_{₀}^{0,j,T}). The comparison may be made by a distance d. That is, the distances d(\hat{Z}^{j}; F(\hat{X}^{j,T})) are computed for each pair (T; j).

The parameters w_{1,m}ⁱ⁻¹, . . . , w_{M}_{ᵢ₋₁}ⁱ⁻¹, m, βₘⁱ, with m from 1 to Mᵢ and i from 1 to N are computed to minimize the distance on the whole training set of vectors \hat{Z}^{j}.

For example, the parameters w_{1,m}ⁱ⁻¹, . . . , w_{M}_{ᵢ₋₁}ⁱ⁻¹, m, βₘⁱ may be computed to minimize for example Σ_{j,T} d(\hat{Z}^{j}; F(\hat{X}^{j,T})) or Σ_{j,T} αⱼ·[d(\hat{Z}^{j}; F(\hat{X}^{j,T}))], where the aⱼ are weighting factors. The parameters w_{1,m}ⁱ⁻¹, . . . , w_{M}_{ᵢ₋₁}ⁱ⁻¹, m, βₘⁱ influences the values taken by F(\hat{X}^{j,T}).

The parameters w_{1,m}ⁱ⁻¹, . . . , w_{M}_{ᵢ₋₁}ⁱ⁻¹, m, βₘⁱ may be computed with a backpropagation method.

As explained in the description related to FIG. 3, the Lattice decoder 3.11 or the ANN-Lattice decoder 7.11 receives n_{Dim}-tuple of real numbers which represents a point P′ (P′₁ or P′₂ on FIG. 4) in [symbol] ⁿ^{_{Dim}}, where n_{Din} is the dimension of the Lattice. Generally, the point P′ is not a point of the Lattice since the noise and the canal have altered the n_{Dim}-tuple of real numbers (representing a point P (P₁ or P₂ on FIG. 4) of the Lattice) outputted by the Lattice encoder 7.2. Therefore, the Lattice decoders must determine to which point of the Lattice Σᵢ₌₁ⁿ^{_{Dim}} zᵢ eᵢ∈ [symbol] ⁿ^{_{Dim}}, with (z₁, . . . , zₙ)∈ [symbol] ⁿ^{_{Dim}}, the point P′ is the closest. To that end the Lattice decoders may determine the position of the point P′ (or a point in the Fundamental domain P″(P″₁ or P″₂ on FIG. 4), which results from a translation of P′ by a vector Σᵢ₌₁ⁿ^{_{Dim}} tᵢ eᵢ, with t₁, . . . , tₙ integers) regarding several hyperplanes (the hyperplanes are the perpendicular bisector hyperplanes of each segment of the Fundamental domain) which divide the Fundamental domain (or the domain which results from a translation of the Fundamental domain by the vector Σᵢ₌₁ⁿ^{_{Dim}}−tᵢ eᵢ in different zones (a, b, c, d, obtained with 5 hyperplanes in the case of FIG. 4). Indeed, all the points of one of the zones are closer to a unique point of the Lattice of the Fundamental domain. Therefore to determine if a point is in one zone, the Lattice decoders may determine on what side of each hyperplane delimiting the zone the point is. For example, in the case of FIG. 4, to determine if a point is in the zone “a”, the Lattice decoder may determine if the point is on the left of the vertical hyperplane delimiting the “a” zone and under the oblique hyperplane delimiting the “a” zone, those two conditions are required. To determine if a point is in the zone “c”, the Lattice decoder may determine if the point is on the right of the vertical hyperplane delimiting the “c” zone and under the two oblique hyperplane delimiting the “c” zone, three conditions are now required. Therefore, even in a two-dimensional Lattice, determining the position of the point P is complex. This complexity grows in a non-linear manner when the dimension of the Lattice becomes bigger. However, even in a two-dimensional lattice determining in what zone the point is, requires at least one node for each hyperplane dividing the Fundamental domain.

In the case of the Lattice of FIG. 4, it requires five activation functions and thus five nodes to determine where a point is in the Fundamental domain. It is possible to reduce this number of nodes. For example, by replacing the activation functions outputting positions of a point relatively to two hyperplanes which are parallel, by one 3-level MLAF. More generally, each edge of the Fundamental domain of an n_{Dim} dimensional Lattice is parallel to 2ⁿ^{_{Dim}}⁻¹−1 other edges of the Fundamental domain. Therefore, when dividing the Fundamental domain, perpendicular bisector hyperplanes of the 2ⁿ^{_{Dim}}⁻¹ parallel edges of the Fundamental domain are used. These 2ⁿ^{_{Dim}}⁻¹ perpendicular bisector hyperplanes may for some of them coincide (but at least 2 hyperplanes do not and most of the time none of them do) or all of them coincide in one hyperplane if the vector of the Lattice basis, which has the same direction as these edges, is orthogonal to all the other vectors of the basis. Therefore, it is possible to reduce the number of nodes of the ANN-Lattice decoder configured with a non-orthogonal Lattice, for example, by replacing the activation functions outputting positions of a point relatively to 2ⁿ^{_{Dim}}⁻¹ hyperplanes which are parallel, by one (2ⁿ^{_{Dim}}⁻¹+1)-level MLAF. These problems are multiclass classification problems which occur regardless to the structure and the training of the ANN system.

Therefore, this complex computing, which requires ANN system with an important amount of nodes implementing regular activation functions, may be carried out by an ANN system with a reduced amount of nodes if MLAFs are implemented in the nodes of the hidden layers.

Therefore, the ANN-Lattice decoder 7.11 is implemented with at least one (2ⁿ^{_{Dim}}⁻¹+1)-levels MLAF (or at least a 3 levels MLAF) on at least one of the hidden layers or on all the hidden layers. All the nodes of a layer may be implemented with such MLAF.

The MLAF used in the embodiment described in FIG. 7 may be defined as:

$${\sum }_{l = 1}^{K - 1} {B}_{l} {f}_{l} ( x - {τ}_{1} ) + A$$

Each ƒₗ are activation function, these activation functions may be the same or different activation function. For example, the ƒₗ may be hyperbolic tangent (Tan H) functions.

The τₗ are distinct real numbers, that is, if l≠l′=>τₗ≠τ_{l′}. This distinction between the τₗ ensures that the activation function has several levels.

The A and the Bₗ are real numbers.
K is an integer equal or greater than (2ⁿ^{_{Dim}}⁻¹+1) (or at least equal or greater than 3).

The parameters K, B₁, . . . , B_{K-1}, A, τ₁, . . . , τ_{K-1} of each MLAF used in the ANN-Lattice decoder 7.11 may be the same for all the MLAFs or may be different for each MLAF or may be the same only for all the MLAFs implemented in the output layer of the ANN system and the same only for all the MLAFs implemented in the hidden layers.

These parameters can be set previously to the training of the ANN-Lattice decoder 7.11 or they can be considered as the parameters of the ANN-Lattice decoder 7.11 which are determined during the training of the ANN system. In that case the parameters are w_{1,m}ⁱ⁻¹, . . . , w_{M}_{ᵢ₋₁}ⁱ⁻¹, m, βₘⁱ, with m from 1 to Mᵢ and i from 1 to N to which are added the parameters of each MLAF used in the ANN-Lattice decoder 7.11.

In the embodiment of FIG. 7 the ANN decoder replaces only the Lattice decoder 3.11. Here, the skilled person understands that the ANN decoder may replace additional components of the receiver scheme settled upstream and downstream from the ANN-Lattice decoder 7.11. For example, the ANN decoder replaces the Lattice decoder 7.11 and may also replace the P/S module 7.10 and the MIMO transmitting unit 7.9 and even the OFDM decoders 7.8.

Here, the skilled person understands that other schemes than the ones implemented in the transmitter 1.1 and the receiver 1.2 could be implemented. The embodiment described in FIG. 7 may be transposed with any other schemes to the condition that there is a Lattice encoder and a Lattice decoder. In that case, the ANN decoder replaces at least the Lattice decoder and may also replace any component placed before or after this Lattice decoder. For example, a shaping module may be added to the scheme described in FIG. 3 between the modulator 3.1 and the lattice encoder 3.2 and inverse shaping module between the demodulator 3.12 and the Lattice decoder 3.11. Such shaping modules modify the sequences of integers inputted in the Lattice encoder 3.2 to ensure that all the possible sequences outputted by the Lattice encoder 3.2 are compact according to the possible sequences of integers outputted by the modulator 3.1. That is, that the possible Lattice points outputted by the Lattice encoder 3.2 according to the possible outputs of the modulator 3.1 are in the smallest possible sphere around zero to reduce the average transmitting power.

Here, the skilled person understands that the ANN system implemented could be different from the feed forward neural network described in FIG. 5, for example, the ANN implemented could be a recurrent neural network.

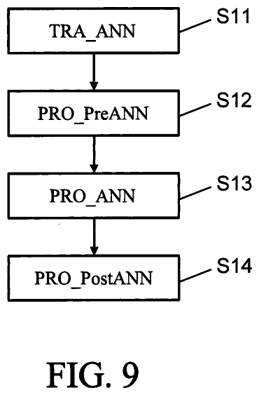

Referring to FIG. 9 is shown a flowchart representing the decoding of a radio signal according to the invention.

At step S11 the ANN decoder, which in the case described in FIG. 6 is the ANN decoder 6.8 and in the case described in FIG. 7 is the ANN-Lattice decoder 7.11, is trained on a training set of vectors \hat{Z}^{j} and their respective associated groups of vectors \hat{X}^{j,T}, as described in FIGS. 6 and 7. The training may be carried out to determine only the parameters w_{1,m}ⁱ⁻¹, . . . , w_{M}_{ᵢ₋₁}ⁱ⁻¹, m, βₘⁱ with m from 1 to Mᵢ and i from 1 to N or these parameters to which are added the parameters defining each MLAF implemented in the ANN system.

The parameters determined may be saved in the MEMO_recei 1.8 and retrieved to configure the ANN system.

At step S12 the radio signal received by the receiver 1.2 is processed by the components settled upstream from the ANN decoder, that is, by the OFDM decoders 6.7 in the embodiment of FIG. 6 and by the OFDM decoders 7.8, the MIMO receiving unit 7.9 and the P/S module 7.10 in the embodiment of FIG. 7.

At step S13 the symbols outputted by the processing carried out at step S12 are inputted into the ANN decoder, which decodes these symbols to retrieve the modulation symbols outputted by the MCS encoder 6.1 in the embodiment of FIG. 6 and the sequence of integers outputted by the modulator 7.1 in the embodiment of FIG. 7 to the condition that the radio channel did not affect too much the radio signal and the noise of the different systems (transmitter 1.1 and receiver 1.2) is limited.

At step S14 the output of the ANN decoder is processed according to the component of the receiver scheme settled at the downstream of the ANN decoder to retrieve the binary sequence which represents the data transmitted.

1-13. (canceled)

14. A method for decoding at least M₀ symbols X₁⁰, . . . , X_{M}_{₀}⁰ received from a transmitter through a wireless communication medium, said received symbols representing symbols encoded by an encoder E of the transmitter, said method comprising:
inputting in a decoder the M₀ symbols X₁⁰, . . . , X_{M}_{₀}⁰ said decoder comprising an artificial neural network system, wherein at least an activation function of the artificial neural network system is a multiple level activation function,
wherein the encoder E comprises a Lattice encoder, wherein inputs of the Lattice encoder being inputs of the encoder E,
wherein the decoder is defined as a function F which is defined by N sets of functions F₁ⁱ, . . . , F_{M}_{ᵢ}ⁱ, with i from 1 to N, Fₘⁱ(X₁ⁱ⁻¹, . . . , X_{M}_{ᵢ₋₁}ⁱ⁻¹)=ƒₘⁱ(Σₖ₌₁^{M}^{ᵢ₋₁} w_{k,m}ⁱ⁻¹×Xₖⁱ⁻¹+βₘⁱ), with F(X₁⁰, . . . , X_{M}_{₀}⁰)=[F₁^{N}(X₁^{N-1}, . . . , X_{M}_{_{N-1}}^{N-1}), . . . , F_{M}_{_{N}}^{N}(X₁^{N-1}, . . . , X_{M}_{_{N-1}}^{N-1})], where, Xₘⁱ⁻¹ are respectively the outputs of the functions Fₘⁱ⁻¹, Xₘⁱ⁻¹=Fₘⁱ⁻¹(X₁ⁱ⁻², . . . , X_{M}_{ᵢ₋₁}ⁱ⁻²) of the (i−1)-th set, each ƒₘⁱ is either an artificial neural network activation function or an identity function, at least one of the ƒₘⁱ is not an identity function and w_{1,m}ⁱ⁻¹, . . . , w_{M}_{_{i-1,m′}}ⁱ⁻¹, βₘⁱ are real number parameters,
wherein at least one of the functions ƒₘⁱ with m from 1 to Mᵢ and i from 1 to N−1 is a multiple level activation function.

15. The method according to claim 14, wherein the artificial neural network system is trained on a training set of vectors \hat{Z}^{j}, each vector \hat{Z}^{j} being compared with the output of the artificial neural network system when applied to a vector \hat{X}^{j,T}, with \hat{X}^{j}=(\hat{X}₁^{0,j}, . . . , \hat{X}_{M}_{₀}^{0,j}), the vectors \hat{X}^{j} being obtained by applying respectively to the vectors \hat{Z}^{j} successively a first transformation representing the encoder E and a second transformation representing at least:
a transmitting scheme of the transmitter, said transmitting scheme following the encoder E, and
a radio communication channel.

16. The method according to claim 14, wherein said parameters w_{1,m}ⁱ⁻¹, . . . , w_{M}_{ᵢ₋₁}ⁱ⁻¹, m, βₘⁱ, with m from 1 to Mᵢ and i from 1 to N are computed to minimize a distance between respectively outputs F(\hat{X}₁^{0,j}, . . . , \hat{X}_{M}_{₀}^{0,j}) of the decoder and vectors \hat{Z}^{j} of a training set of vectors, with \hat{Z}^{j}=(\hat{Z}₁^{j}, . . . , \hat{Z}_{M}_{_{N}}^{j}),
the vectors \hat{X}^{j}, with \hat{X}^{j}=(\hat{X}₁^{0,j}, . . . , \hat{X}_{M}_{₀}^{0,j}), being obtained by applying respectively to the vectors \hat{Z}^{j} successively a first transformation representing the encoder E and a second transformation representing at least:
a transmitting scheme of the transmitter, said transmitting scheme following the encoder E, and
a wireless communication channel.

17. The method according to claim 14, wherein the multiple level activation function is defined as:
$${f}_{K , {B}_{1} , … , {B}_{K - 1} , A , {τ}_{1} , … , {τ}_{K - 1}} ( x ) = {{\sum }^{K - 1}}_{l = 1} {B}_{l} {f}_{l} ( x - {τ}_{l} ) + A \qquad$$
with each ƒₗ being an activation function,
with τₗ being real numbers, and if l≠l′=>τₗ≠τ_{l′},
with A and the Bₗ being real numbers
and K a positive integer greater than or equal to 3.

18. The method according to claim 14, wherein the encoder E comprises a MIMO encoder.

19. A computer program product comprising code instructions to perform the method according to claim 14, when said instructions are run by a processor.

20. A device for receiving M₀ symbols X₁⁰, . . . , X_{M}_{₀}⁰ from a transmitter through a wireless communication medium, said received symbols representing symbols encoded by an encoder E of the transmitter, the device comprises:
a reception module; and
a decoder, said decoder comprising an artificial neural network system, wherein at least an activation function of the artificial neural network system is a multiple level activation function,
wherein the encoder E comprises a Lattice encoder, wherein inputs of the Lattice encoder being inputs of the encoder E,
wherein the decoder is defined as a function F which is defined by N sets of functions F₁ⁱ, . . . , F_{M}_{ᵢ}ⁱ, with i from 1 to N, Fₘⁱ(X₁ⁱ⁻¹, . . . , X_{M}_{ᵢ₋₁}ⁱ⁻¹)=ƒₘⁱ(Σₖ₌₁^{M}^{ᵢ₋₁} w_{k,m}ⁱ⁻¹×Xₖⁱ⁻¹+βₘⁱ), with F(X₁⁰, . . . , X_{M}_{₀}⁰)=[F₁^{N}(X₁^{N-1}, . . . , X_{M}_{_{N-1}}^{N-1})], . . . , F_{M}_{_{N}}^{N}(X₁^{N-1}, . . . , X_{M}_{_{N-1}}^{N-1})), where, Xₘⁱ⁻¹ are respectively the outputs of the functions Fₘⁱ⁻¹, Xₘⁱ⁻¹=Fₘⁱ⁻¹(X₁ⁱ⁻², . . . , X_{M}_{ᵢ₋₁}ⁱ⁻²) of the (i−1)-th set, each ƒₘⁱ is either an artificial neural network activation function or an identity function, at least one of the ƒₘⁱ is not an identity function and w_{1,m}ⁱ⁻¹, . . . , w_{M}_{_{i-1,m′}}ⁱ⁻¹, βₘⁱ are real number parameters,
wherein at least one of the functions ƒₘⁱ with m from 1 to Mᵢ and i from 1 to N−1 is a multiple level activation function.
